(19) United States
(12) Patent Application Publication
(10) Pub. No.: US 2026/0150447 A1
(43) Pub. Date: May 28, 2026

(54) MICRO LED DISPLAY PANEL, MANUFACTURING METHOD THEREOF AND DISPLAY DEVICE

(71) Applicant: JADE BIRD DISPLAY (SHANGHAI) LIMITED, SHANGHAI (CN)

(72) Inventor: Peng CHEN, Shanghai (CN)

(21) Appl. No.: 19/398,068

(22) Filed: Nov. 24, 2025

(30) Foreign Application Priority Data
Nov. 27, 2024 (WO) PCT/CN2024/134859
Nov. 27, 2024 (WO) PCT/CN2024/134869
Nov. 27, 2024 (WO) PCT/CN2024/134878
Nov. 27, 2024 (WO) PCT/CN2024/134881
Nov. 27, 2024 (WO) PCT/CN2024/134886
Nov. 27, 2024 (WO) PCT/CN2024/134890
Nov. 27, 2024 (WO) PCT/CN2024/134893

(51) Int. Cl. H10H 20/854; H05K 1/18; H10H 20/01; H10H 20/857

(52) U.S. Cl. CPC H10H 20/854; H05K 1/189; H10H 20/0362; H10H 20/857; H05K 2201/10128

(57) ABSTRACT

A micro LED element, a micro LED display panel, and a display device are provided. The micro LED display panel includes a micro LED chip including a driving layer and a micro LED array disposed on the driving layer, the driving layer being configured to receive signals for driving the micro LED array; a flexible circuit board (FCB) disposed adjacent to the micro LED chip and configured to couple to the micro LED chip; a molded layer disposed to join the micro LED chip and the FCB together, to leave an open region above the micro LED array; and a transparent cover disposed within the open region to shield a top surface of the micro LED array.

### CROSS-REFERENCE TO RELATED APPLICATIONS

The present disclosure claims the benefits of priority to PCT Application Nos. PCT/CN2024/134859, PCT/CN2024/134869, PCT/CN2024/134878, PCT/CN2024/134881, PCT/CN2024/134886, PCT/CN2024/134890, and PCT/CN2024/134893, all filed on Nov. 27, 2024, and all of which are incorporated herein by reference in their entireties.

### TECHNICAL FIELD

The present disclosure generally relates to micro display technology, and more particularly, to a micro LED display panel, a method of manufacturing the micro LED display panel, and a display device.

### BACKGROUND

Inorganic micro pixel light emitting diodes, also referred to as micro light emitting diodes, micro LEDs, or μ-LEDs, become more important since they are used in various applications including self-emissive micro-displays, visible light communications, and optogenetics. The micro LEDs have higher output performance than conventional LEDs because of better strain relaxation, improved light extraction efficiency, and uniform current spreading. Compared with conventional LEDs, the micro LEDs also exhibit several advantages, such as improved thermal effects, faster response rate, larger working temperature range, higher resolution, wider color gamut, higher contrast, lower power consumption, and operability at higher current density.

A micro LED display panel is manufactured by integrating an array of thousands or even millions of micro LEDs with an integrated circuit (IC) back panel. In conventional techniques, micro LEDs can be packaged on the IC back panel, where an array of micro LEDs forms a light-emitting area in a functional region on a front side of the IC back panel. Meanwhile, a non-functional area on the front side of the IC back panel can be used for electrodes, which can create an I/O port for voltage and signal transmission. This packaging arrangement results in a larger micro LED product, requiring more space, and thereby hindering its application in space-constrained products.

Therefore, there is a need for improving the packaging of micro LEDs.

### SUMMARY OF THE DISCLOSURE

Some embodiments of the present disclosure provide a micro LED display panel. The micro LED display panel includes a micro LED chip including a driving layer and a micro LED array disposed on the driving layer, the driving layer being configured to receive signals for driving the micro LED array; a flexible circuit board (FCB) disposed adjacent to the micro LED chip and configured to couple to the micro LED chip; a molded layer disposed on the micro LED chip and the FCB to join the micro LED chip and the FCB together, leaving an open region above the micro LED array; and a transparent cover disposed within the open region to shield a top surface of the micro LED array.

Some embodiments of the present disclosure provide a method of manufacturing a micro LED display panel, including coupling a flexible circuit board (FCB) to a micro LED chip having a driving layer and a micro LED array disposed on the driving layer, the driving layer being configured to receive signals for driving the micro LED array, the FCB being disposed adjacent to the micro LED chip and configured to couple to the micro LED chip; forming a molded layer to bond the micro LED chip and the FCB into a single structure, leaving an open region above the micro LED array; and disposing a transparent cover within the open region to cover a top surface of the micro LED array.

Some embodiments of the present disclosure provide a display device. The display device includes any of the micro LED display panels disclosed herein.

### BRIEF DESCRIPTION OF THE DRAWINGS

Embodiments and various aspects of the present disclosure are illustrated in the following detailed description and the accompanying figures. Various features shown in the figures are not drawn to scale.

FIG. 1A illustrates a structural diagram showing a front side of an exemplary micro LED display panel, according to some embodiments of the present disclosure.

FIG. 1B illustrates a structural diagram showing a back side of the exemplary micro LED display panel shown in FIG. 1A, according to some embodiments of the present disclosure.

FIG. 2A illustrates a structural diagram showing a sectional view of the exemplary micro LED display panel along section line A-A shown in FIG. 1A, according to some embodiments of the present disclosure.

FIG. 2B illustrates a structural diagram showing a sectional view of the exemplary micro LED display panel along section line A-A shown in FIG. 1A, according to some embodiments of the present disclosure.

FIG. 3A illustrates a structural diagram showing a micro LED chip of the exemplary micro LED display panel shown in FIGS. 1A, 2A and 2B, according to some embodiments of the present disclosure.

FIG. 3B illustrates a structural diagram showing a micro LED chip of another exemplary micro LED display panel, according to some embodiments of the present disclosure.

FIG. 3C illustrates a structural diagram showing a micro LED chip of another exemplary micro LED display panel, according to some embodiments of the present disclosure.

FIG. 4A illustrates a structural diagram showing a front side of another exemplary micro LED display panel, according to some embodiments of the present disclosure.

FIG. 4B illustrates a structural diagram showing a back side of the exemplary micro LED display panel shown in FIG. 4A, according to some embodiments of the present disclosure.

FIG. 5A illustrates a front side of an exemplary display device having a plurality of micro LED display panels, according to some embodiments of the present disclosure.

FIG. 5B illustrates a back side of the exemplary display device shown in FIG. 5A, according to some embodiments of the present disclosure.

FIG. 6 illustrates a structural diagram showing another exemplary display device having a combiner, according to some embodiments of the present disclosure.

FIG. 7 illustrates a flowchart of an exemplary method of manufacturing a micro LED display panel, according to some embodiments of the present disclosure.

FIG. 8 illustrates a structural diagram showing another exemplary display device, according to some embodiments of the present disclosure.

FIG. 9 illustrates a structural diagram showing another exemplary display device, according to some embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the invention. Instead, they are merely examples of apparatuses and methods consistent with aspects related to the invention as recited in the appended claims. Particular aspects of the present disclosure are described in greater detail below. The terms and definitions provided herein control, if in conflict with terms and/or definitions incorporated by reference.

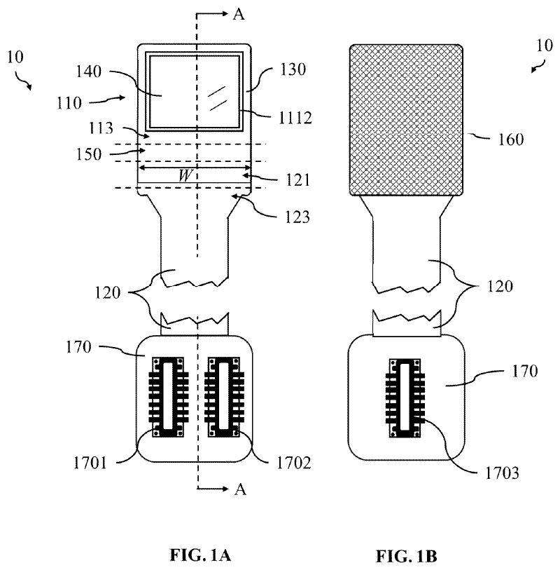

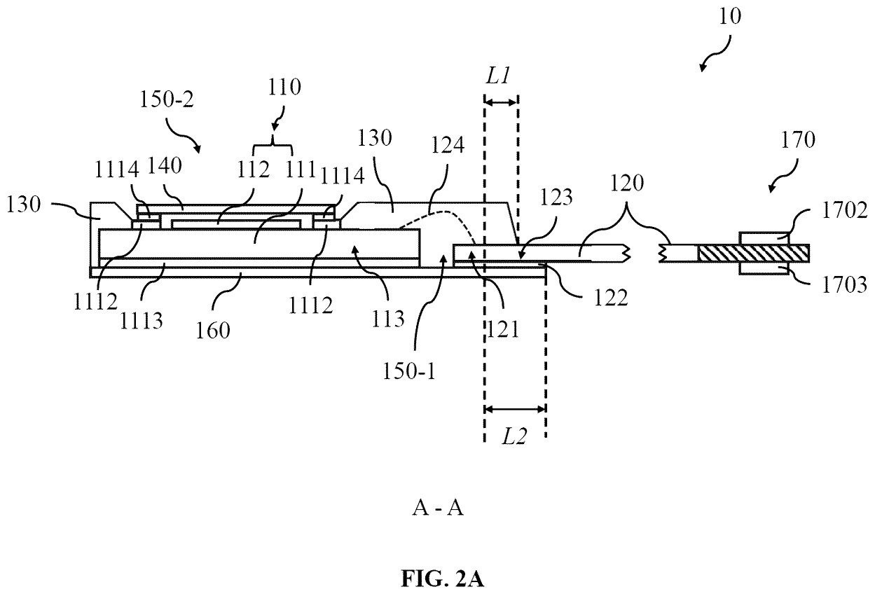

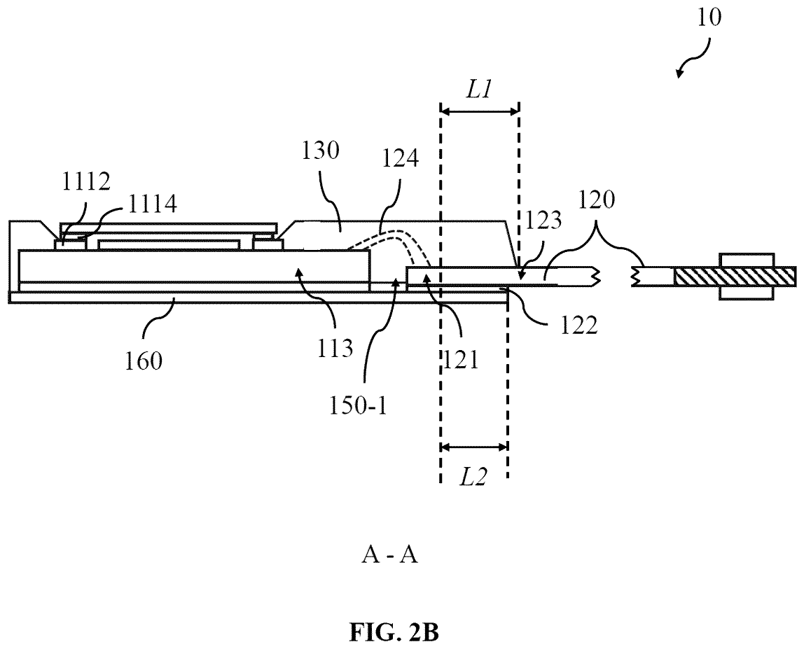

FIGS. 1A and 1B illustrate structural diagrams showing an exemplary micro LED display panel 10, according to some embodiments of the present disclosure. FIG. 2A illustrates a structural diagram showing a sectional view of exemplary micro LED display panel 10 along section line A-A in FIG. 1A, according to some embodiments of the present disclosure. FIG. 2B illustrates a structural diagram showing a sectional view of exemplary micro LED display panel 10 along section line A-A in FIG. 1A, according to some embodiments of the present disclosure. As shown in FIGS. 1A, 1B, 2A and 2B, micro LED display panel 10 includes a micro LED chip 110, a flexible circuit board (FCB) 120 (e.g., a flexible printed circuit board), a molded layer 130, and a transparent cover 140. The manufacturing process includes creating molded layer 130 on a portion of micro LED chip 110 as well as FCB 120, so that micro LED chip 110 and FCB 120 are then joined together as a single compact structure. In some embodiments, the molding process can also be transfer molding, injection molding, compression molding, extrusion molding, hollow molding, etc. In some embodiments, the molding material of molded layer 130 can be epoxy molding compound(EMC), acrylic (Polymethyl Methacrylate), acrylonitrile butadiene styrene (ABS), nylon polyamide (PA), polycarbonate (PC), polyethylene (PE), etc. This resulting assembly is diminutive and can be seamlessly incorporated into a display device. For example, during the deposition process, molded layer 130 with a high-temperature capability can be applied onto micro LED chip 110 and FCB 120. At an elevated temperature, the molding material adopts a softer consistency, allowing it to envelop micro LED chip 110 and FCB 120. After cooling and hardening, molded layer 130 effectively encloses and bonds to micro LED chip 110 and FCB 120, uniting micro LED chip 110 and FCB 120 as a cohesive entity. Furthermore, transparent cover 140 can be disposed on or above micro LED chip 110 to protect micro LED chip 110.

As shown in FIG. 2A, micro LED chip 110 includes a driving layer 111 and a micro LED array 112 disposed on driving layer 111. Driving layer 111 may include a driving circuit (not shown) for driving micro LED array 112 with received signals. Specifically, driving layer 111 may include a signal zone 113 for receiving the signals for driving micro LED array 112 and passing the signals to the driving circuit. Micro LED array 112 is not disposed on signal zone 113 in order to provide space for leading out electrodes which can be coupled to electrodes within FCB 120.

For the compact structure of micro LED display panel 10, FCB 120 can be disposed adjacent to signal zone 113 to shorten a total length of micro LED display panel 10. A distance between micro LED chip 110 and FCB 120 can be from one millimeter to several millimeters. In some embodiments, the distance between micro LED chip 110 and FCB 120 can be set according to the adhesion of a molding material of molded layer 130, such that the assembly of micro LED chip 110 and FCB 120 will not be broken by applied forces. It is appreciated that micro LED chip 110 and FCB 120 may be disposed apart at a greater distance, in which case a thicker molding material may need to be used for molded layer 130, when the adhesion of the molding material is relatively low.

In some embodiments, FCB 120 includes a connection zone 121 for leading out electrodes. FCB 120 can be coupled to signal zone 113 of driving layer 111 in connection zone 121 of FCB 120. As can be appreciated, FCB 120 may not generate the signals for driving micro LED array 112, but it can pass these signals and thus function as a medium for transmitting signals and power. These signals can be generated by a graphic processing unit (GPU) connected to FCB 120.

With further reference to FIGS. 1A, 1B, 2A and 2B, molded layer 130 can be disposed to bond to and join micro LED chip 110 and FCB 120 (e.g., connection zone 121 of FCB 120) into the single compact structure. As described above, molded layer 130 can be disposed on a portion of outer surfaces of micro LED chip 110 and FCB 120 and bond micro LED chip 110 and FCB 120 together. More particularly, molded layer 130 can be formed to fill a gap 150-1 between micro LED chip 110 and FCB 120 as well as formed on a side surface and a portion of a front surface of driving layer 111 on which micro LED chip 110 is formed, and an end portion of FCB 120. The integrated molded layer 130 joins micro LED chip 110 and FCB 120 into the single compact structure. As shown in FIG. 2A, molded layer 130 can be disposed to leave an open region 150-2 above micro LED array 112, though which micro LED array 112 can emit light representing images that are rendered according to the received signals described above. Herein, molded layer 130 can join micro LED chip 110 and FCB 120 without affecting the display of micro LED array 112.

In some embodiments, open region 150-2 is formed with a specific shape having a periphery defined by molded layer 130. For example, open region 150-2 can be formed with a trapezoidal cross section and with an outwardly widening opening structure, or it can be formed with a rectangular cross section. During the deposition process to form molded layer 130, open region 150-2 can be occlued by a mold used to form molded layer 130. The molding material cannot be filled in a space occupied by the mold. When molded layer 130 hardens, the mold can be removed to expose open region 150-2. The outwardly widening opening structure or a rectangular cross section structure of open region 150-2, defined by the periphery of molded layer 130, facilitates easier demolding. As can be appreciated, the mold can be removed upwardly without damaging molded layer 130 that has already hardened.

Moreover, the outwardly widening opening structure decreases undesired reflections by and between inside wall of open region 150-2. Such internal reflections within open region 150-2 could blur the image rendered by micro LED array 112, which could deteriorate display quality. With the outwardly widening opening structure, most of the light from micro LED array 112 can be emitted through open region 150-2 and reach a viewer's eyes directly. In some embodiments, some light from micro LED array 112 can be emitted through open region 150-2 with limited reflections. As shown in FIGS. 1A and 2A, micro LED array 112 is totally exposed from open region 150-2. That is, the emitted light from micro LED array 112 can be seen from above open region 150-2 within a certain viewing angle (e.g., within an angle range of eighty-five degrees from a central normal axis of micro LED array 112).

As shown FIG. 2A, transparent cover 140 can be disposed within open region 150-2 to shield a top surface of micro LED array 112. That is, transparent cover 140 can be disposed on or above the top surface of micro LED array 112 to protect micro LED array 112. For example, transparent cover 140 can be disposed directly on the whole top surface of micro LED array 112, or transparent cover 140 can be spaced from the top surface of micro LED array 112 at a distance from 1 μm to 500 μm. In some embodiments, transparent cover 140 may include an adhesive layer (not shown) that is adhered to driving layer 111, around the top surface of micro LED array 112. Although the adhesive layer can be transparent to light, it may absorb the light emitted from micro LED array 112 to some extent. By disposing the adhesive layer onto driving layer 111, transparent cover 140 can be secured to micro LED chip 110 without affecting the light efficiency of micro LED array 112. In some embodiments, the adhesive layer can be formed by epoxy adhesive, thermosetting adhesive, moisture adhesive, etc. In some embodiments, transparent cover 140 does not contact molded layer 130. Specifically, a side surface of transparent cover 140 is spaced from molded layer 130 at a distance from 1 μm to 1000 μm.

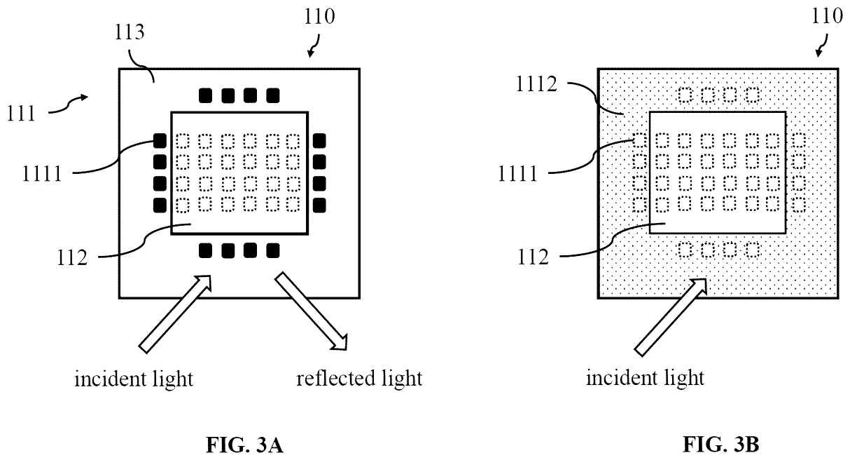

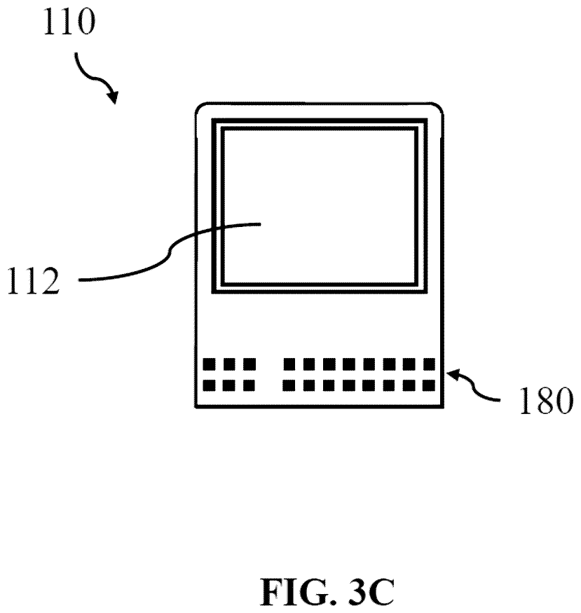

FIGS. 3A and 3B illustrate a structural diagram showing micro LED chip 110 of exemplary micro LED display panel 10, according to some embodiments of the present disclosure. For a clear illustration of the circuitry structure, some of the components shown in FIGS. 3A and 3B may not be viewable from outside and are shown with dashed lines. As shown in FIG. 3A, molded layer 130 and transparent cover 140 are omitted for a better understanding of the layout of micro LED chip 110. Micro LED array 112 can be formed on a surface of driving layer 111 and coupled to driving layer 111. In addition, driving layer 111 may include metal pads 1111 arranged in signal zone 113 on the same surface of driving layer 111 on which micro LED array 112 is formed. Some of metal pads 1111 can be coupled to corresponding electrodes of micro LED array 112 for coupling therebetween. Due to the property of metals, metal pads 1111 can reflect light incident on them (denoted as “incident light” in FIGS. 3A and 3B). Some of the light emitted by micro LED array 112 is inevitably incident on metal pads 1111, for example, by single or multiple reflections. Such reflected light (denoted as “reflected light” in FIG. 3A) from metal pads 1111 may blur and deteriorate the images rendered by micro LED array 112.

To prevent this, as shown in FIG. 3B, a light shading layer 1112 can be further disposed on metal pads 1111 of driving layer 111. Light shading layer 1112 can absorb light incident thereon and thus improve the quality of the images rendered by micro LED array 112. For example, light shading layer 1112 can be black photoresist and its thickness can be several microns. In some embodiments, light shading layer 1112 can also be light-shielding film with black or dark color. In some embodiments, light shading layer 1112 can be adhered to transparent cover 140. For example, an adhesive layer 1114 of transparent cover 140 can be adhered to light shading layer 1112 and around the top surface of the micro LED array 112. As can be appreciated, adhesive layer 1114 disposed on light shading layer 1112 need not be transparent. In addition, as the side surface of transparent cover 140 can be spaced from molded layer 130, light shading layer 1112 can be viewed from directly above as shown in FIGS. 1A, 2A and 2B.

In some embodiments, as shown in FIG. 3A, at least some of metal pads 1111 can be formed around micro LED array 112. Light shading layer 1112 in FIG. 3B can also be formed around micro LED array 112 without leaving a gap between micro LED array 112 and molded layer 130 (not shown in FIG. 3B). That is, light shading layer 1112 is formed to cover all metal pads 1111, and any region other than micro LED array 112 exposed on open region 150-2 can be shielded by light shading layer 1112 when viewed from above open region 150-2. A height of light shading layer 1112 can be the same as a height of micro LED array 112. As used herein, a height of an object is a distance of the highest part of the object from a reference plane (e.g., a bottom surface of a substrate layer 160 which is described below). For example, the height of light shading layer 1112 is the distance between a top surface of light shading layer 1112 and a back surface of substrate layer 160. In this regard, the top surface of light shading layer 1112 can be aligned with the top surface of micro LED array 112. In some embodiments, as shown in FIG. 2A, the height of light shading layer 1112 can be higher than the height of micro LED array 112. In some embodiments, molded layer 130 can be disposed adjacent to light shading layer 1112 but not on light shading layer 1112. In some embodiments, molded layer 130 can be disposed adjacent to and on light shading layer 1112, as shown in FIG. 2B. As can be appreciated, the height of light shading layer 1112 shown in FIG. 2B can be different from that shown in FIG. 2A.

FIG. 3C illustrates a structural diagram showing a micro LED chip of another exemplary micro LED display panel, according to some embodiments of the present disclosure. As shown in FIG. 3C, a plurality of electrodes 180 can be used to lead out traces 124 shown in FIGS. 2A and 2B. As can be appreciated, electrodes 180 are connected to micro LED array 112.

With further reference to FIGS. 1B, 2A and 2B, micro LED display panel 10 further includes substrate layer 160, which is disposed cooperatively with molded layer 130 to join micro LED chip 110 and at least a portion of FCB 120. For example, molded layer 130, micro LED chip 110, and connection zone 121 of FCB 120 can be disposed on a front surface of substrate layer 160. Substrate layer 160, on one hand, can provide mechanical rigidity to surface components (e.g., micro LED chip 110, FCB 120, etc.) disposed thereon. On the other hand, substrate layer 160 can be adhered to molded layer 130 when molded layer 130 cools and hardens. As such, molded layer 130, along with substrate layer 160, can provide a sealed or semi-sealed environment for the surface components. In some embodiments, substrate layer 160 can be formed by a steel plate. As can be appreciated, other materials can also be used to form substrate layer 160, as long as they can provide functionality similar to the steel plate. For example, substrate layer 160 can also be formed by ceramics, hard resin, etc.

In some embodiments, a bottom surface of micro LED chip 110 can be aligned with a bottom surface of FCB 120. That is, a height of the bottom surface of micro LED chip 110 can be the same as the bottom surface of FCB 120.

In some embodiments, as shown in FIG. 2A, FCB 120 may include an adhesive layer 122 that is adhered to the front surface of substrate layer 160. A bottom surface of adhesive layer 122 can be aligned with a bottom surface of micro LED chip 110. That is, adhesive layer 122 and micro LED chip 110 can be attached to substrate layer 160 which is a planar plate. In some embodiments, the bottom surface of adhesive layer 122 may not be aligned with the bottom surface of micro LED chip 110. In some embodiments, adhesive layer 122 can be conductive and its thickness can be from 5 μm to 50 μm. By this arrangement, FCB 120 can electrically couple to substrate layer 160 which can be a common equipotential component in a display device including micro LED display panel 10. For example, FCB 120 can be connected to the ground when substrate layer 160 is connected to the ground. Although not shown, FCB 120 may include a conductive line which acts as a ground wire and couples to ground potentials of the components connected to FCB 120. In some embodiments, adhesive layer 122 can be electrically isolated while the FCB 120 need not to be connected to the ground.

In some embodiments, driving layer 111 further includes an adhesive layer 1113 that is adhered to the front surface of substrate layer 160. A bottom surface of adhesive layer 1113 can be aligned with a bottom surface of FCB 120. Specifically, the bottom surface of adhesive layer 1113 can be aligned with the bottom surface of adhesive layer 122 if present. In some embodiments, adhesive layer 1113 is insulative and electrically isolates driving layer 111 from substrate layer 160. As driving layer 111 may include several electrodes or solder points on its bottom surface, the back surface of driving layer 111 may need to be insulated from the external environment. For example, adhesive layer 1113 can be formed by a Die Attach (DA) adhesive or Die Attach Film (DAF) adhesive. In some embodiments, the bottom surface of adhesive layer 1113 may not be aligned with the bottom surface of FCB 120.

In some embodiments, a thickness of adhesive layer 122 can be similar to a thickness of adhesive layer 1113. In other embodiments, the thickness of adhesive layer 122 can be less than the thickness of adhesive layer 1113.

In some embodiments, adhesive layer 122 is merely disposed on a bottom surface of connection zone 121, while substrate layer 160 can be disposed below connection zone 121 via adhesive layer 122. In some embodiments, as shown in FIG. 2A, adhesive layer 122 can be further disposed below a bottom surface of a region 123 adjacent to connection zone 121, while substrate layer 160 is further disposed below region 123 adjacent to connection zone 121 via adhesive layer 122. Boundaries of connection zone 121 and region 123 are shown as dashed lines in FIG. 2A. As FCB 120 is flexible and may be relatively fragile, disposing a longer region of FCB 120 on substrate layer 160 can enhance its reliability in the encapsulation of connection zone 121 created by molded layer 130 and substrate layer 160.

In some embodiments, molded layer 130 can be further formed on FCB 120 at a distance L1 extending from connection zone 121. As can be appreciated, a longer disposition of molded layer 130 on FCB 120 increases adhesion between molded layer 130 and FCB 120. It can enhance reliability of FCB 120 in the encapsulation created by molded layer 130 and substrate layer 160. In some embodiments, the distance L1 extending from connection zone 121 may be equal to or differ from length L2 of region 123 adjacent to connection zone 121. For example, as shown in FIG. 2B, the distance L1 can be longer than length L2 (e.g., the distance L1 can be 0.05 mm longer than length L2).

In some embodiments, FCB 120 includes conductive traces 124 that are led out from connection zone 121. FCB 120 can be coupled to signal zone 113 via traces 124. In some embodiments, as shown in FIG. 2A, molded layer 130 can be further disposed to encapsulate traces 124. In some embodiments, traces 124 may include a bunch of wires that are led out from different places of signal zone 113 and connection zone 121, as shown in FIG. 2B.

In some embodiments, a height of molded layer 130 is higher than or equals to a height of micro LED array 112. A higher molded layer 130 can provide extra protection to micro LED array 112, while a lower molded layer 130 can provide a more compact design of micro LED display panel 10.

In some embodiments, as shown in FIG. 1A, a width W of molded layer 130 corresponds to a width of connection zone 121. That is, the width of molded layer 130 may basically be equal to the width of connection zone 121, ignoring the manufacturing tolerance and a thin deposition of molded layer 130 at edges of FCB 120. In some embodiments, the width of molded layer 130 can be greater than all regions of FCB 120 other than connection zone 121 of FCB 120. In other words, connection zone 121 is the widest area within FCB 120, so as to guarantee the rigidity of the connected two parts.

In some embodiments, as shown in FIGS. 1A, 1B, 2A and 2B, micro LED display panel 10 may include a hard circuit board 170 provided at an opposite end to connection zone 121 on FCB 120, and electrically coupled to FCB 120. Hard circuit board 170 may include one or more connectors. In this example, hard circuit board 170 includes connectors 1701 and 1702 at one surface and a connector 1703 at an opposite surface. Connectors 1701, 1702 and 1703 can be connected to other hard circuit boards of other micro LED display panels or other processing units with pin-slot connections. Herein, the connectors are not specified as pin-slot configuration, as long as they can be used for I/O communication with external devices.

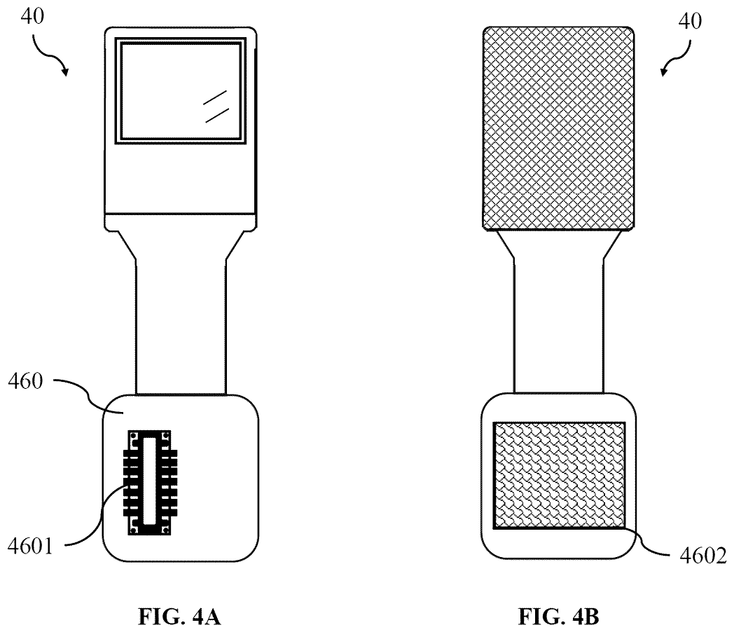

FIG. 4A illustrates a structural diagram showing a front side of another exemplary micro LED display panel 40, FIG. 4B illustrates a structural diagram showing a back side of exemplary micro LED display panel 40, according to some embodiments of the present disclosure. Micro LED display panel 40 shows much in common with micro LED display panel 10 described above. However, micro LED display panel 40 includes a hard circuit board 460. In some embodiments, hard circuit board 460 may have a shape and functionality different from hard circuit board 170 of micro LED display panel 10. Specifically, hard circuit board 460 includes a memory chip 4602. In some embodiments, hard circuit board 460 may further include a cover arranged on or above memory chip 4602 for protecting memory chip 4602. Hard circuit board 460 also includes a connector 4601 at one surface and memory chip 4602 at an opposite surface to connector 4601. Connector 4601 and memory chip 4602 are connected together for storing data into and outputting data from memory chip 4602 through connector 4601. For example, memory chip 4602 may cache or store patterns to display or instructions for displaying patterns for micro LED display panel 40, which may reduce the communication cost between micro LED display panel 40 and a signal source (for example, a GPU), thereby improving display efficiency

Micro LED display panel 10 with connectors 1701 to 1703 on two surfaces shown in FIGS. 1A, 1B, 2A and 2B can be used as a hub for connecting with micro LED display panel 40. The other aspects of micro LED display panel 40 can be understood by referring to the description of micro LED display panel 10 with reference to FIGS. 1A, 1B, 2A and 2B, and will not be described in detail here. It can be understood that micro LED display panel 10 with reference to FIGS. 1A, 1B, 2A and 2B can further include a memory chip coupled with one or more of connectors 1701, 1702, 1703.

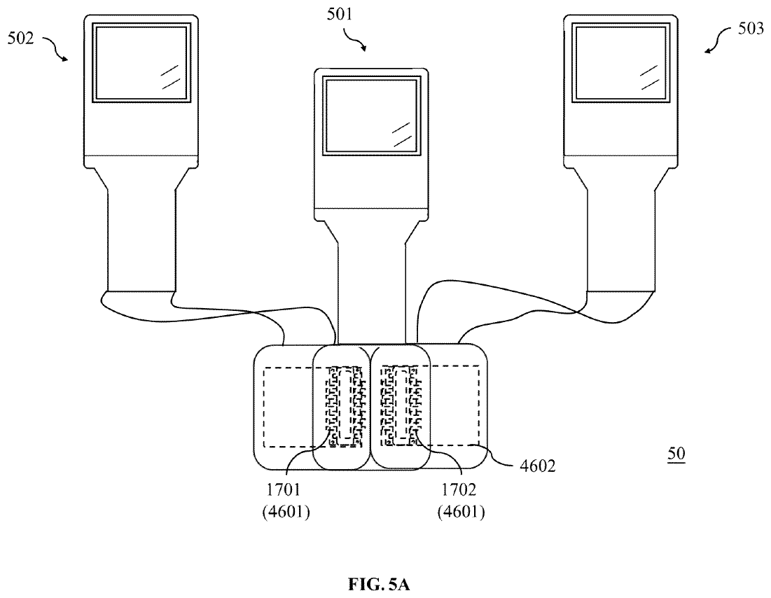

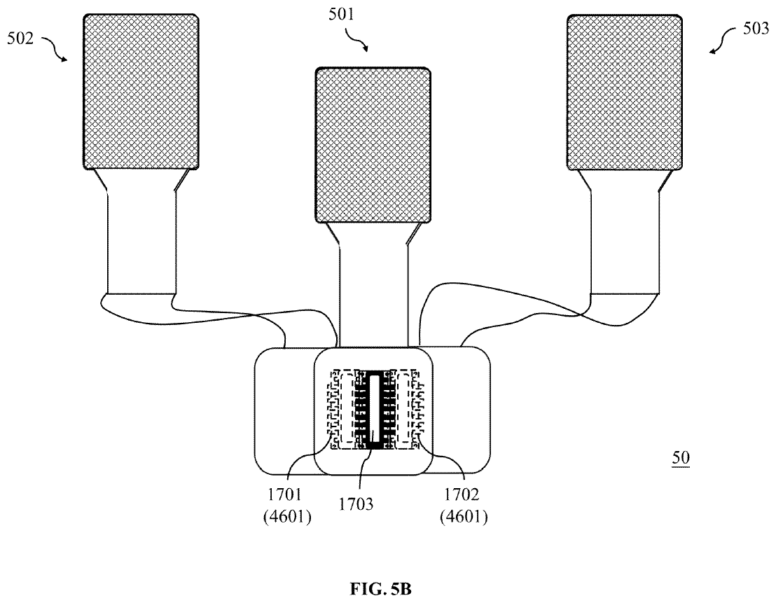

FIG. 5A illustrates a front side of an exemplary display device 50 having a micro LED display panel 501 (e.g., corresponding to micro LED display panel 10 in FIGS. 1A, 1B, 2A and 2B) and micro LED display panels 502 and 503 (e.g., each corresponding to micro LED display panel 40 in FIGS. 4A and 4B), FIG. 5B illustrates a back side of exemplary display device 50, according to some embodiments of the present disclosure. For a clear illustration of coupling relationships between connectors, some of the components shown in FIGS. 5A and 5B may not be viewable from outside and are shown with dashed lines.

As shown in FIG. 5A, connectors 4601 of micro LED display panels 502 and 503 are inserted into connectors 1701 and 1702 of micro LED display panel 501 respectively, which forms exemplary display device 50 having three collaborative micro LED display panels. More particularly, panels 502 and 503 can be turned over by twisting respective FCB's, so that connectors 4601 of panels 502 and 503 face connectors 1701 and 1702 of micro LED display panel 501, respectively. These micro LED display panels can be driven by signals received from micro LED display panel 501, specifically through connector 1703 on a back side of micro LED display panel 501, as shown in FIG. 5B. Connector 1703 can be connected to an external device that generates the signals. As can be appreciated, micro LED display panels 501, 502, and 503 can be used to display red components, green components, and blue components of a composite image, respectively. That is, micro LED display panel 501 may render a red image, micro LED display panel 502 may render a green image, and micro LED display panel 503 may render a blue image.

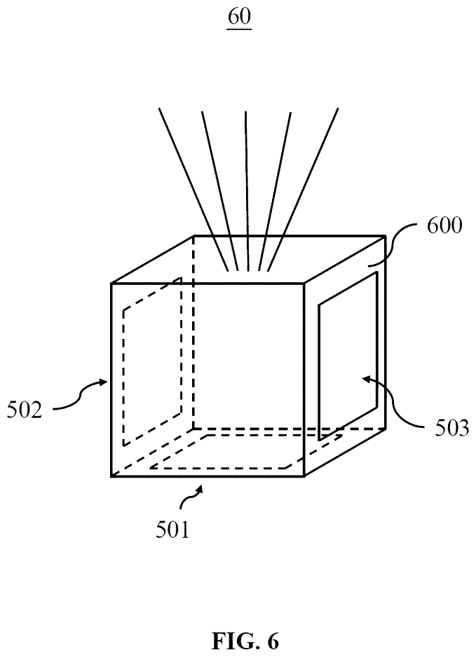

FIG. 6 illustrates another exemplary display device 60 having a combiner 600, according to some embodiments of the present disclosure. Referring to FIG. 6, display device 60 (e.g., a polychrome projector) includes micro LED display panel 501, micro LED display panel 502, and micro LED display panel 503, shown in FIGS. 5A and 5B, and a combiner 600 (e.g., a combining prism). Combiner 600 can be used to combine (also referred to as “compositing”) the images rendered by micro LED display panel 501, micro LED display panel 502, and micro LED display panel 503 into a composite image. As will be appreciated, display device 60 may also include other necessary components for operation that are omitted here.

As described above, micro LED display panel 501 may render a red image, micro LED display panel 502 may render a green image, and micro LED display panel 503 may render a blue image, which can be composited through combiner 600 to form a polychrome image. The red image, the green image, and the blue image can be aligned after passing through combiner 600 to form the polychrome image.

In some embodiments, micro LED chip 110 includes an integrated circuit (IC) backplane (e.g., driving layer 111 shown in FIGS. 2A and 3A). Micro LED array 112 includes multiple micro LEDs (not shown). Each micro LED may form at least a portion of a pixel element on micro LED chip 110. For example, the pixel element can be formed by a single micro LED for a monochrome display, and can be formed by three micro LEDs for a color display. In some embodiments, each dimension of micro LED chip 110 is not more than 1 centimeter (cm), preferably, not more than 20 micrometers (μm). A resolution of micro LED array 112 can be 720×480, 640×480, 1920×1080, 1280×720, 2K (i.e., 2048×1080), or 4K (i.e., 3840×2160). A diameter of the micro LED is at a nanometer level, e.g., 20 nm to 100 nm. In some embodiments, the pitch of micro LED array 112, i.e., the minimum center-to-center distance between adjacent micro LEDs, may range from 2 μm to 50 μm. In some embodiments, the number of pixels in micro LED chip 110 may range from several thousands to over several millions. In some embodiments, micro LED array 112 may include blue micro LEDs, green micro LEDs, or red micro LEDs.

In some embodiments, the IC backplane may be electrically connected to each micro LED of micro LED array 112 through separate metal interconnects. In some embodiments, each micro LED may be separately, electrically controlled by the IC backplane. In some embodiments, the IC backplane may be electrically connected to an electrode of micro LED chip 110 through a metal interconnect. In some embodiments, a dielectric layer may be formed in the gap between the micro LEDs. In some embodiments, the dielectric layer may also be formed in the gap between metal interconnects.

In some embodiments, each micro LED of micro LED array 112 may include a micro mesa structure. In some embodiments, the micro mesa structure may include a first type epitaxial layer, a light emitting layer, and a second type epitaxial layer, from bottom up. That is, among the three layers, the first type epitaxial layer is closest to the IC backplane; the light emitting layer is on top of the first type epitaxial layer and is further away from the IC backplane; the second type epitaxial layer is on top of the light emitting layer and is the furthest away from the IC backplane. In some embodiments, the light emitting layer is formed by several stacked quantum well layers, especially super crystal stacked quantum well layers. Preferably, the super crystal stacked quantum well layers include multiple pairs of a quantum well layer stacked with a quantum barrier layer. In some embodiments, the first type epitaxial layer is a semiconductor material with a first conductive type and includes several semiconductor layers. The main body material of the first type epitaxial layer can be but not limited to base materials including one or more of Ga, N, As, P, In, or Al etc. Additionally, the first type epitaxial layer can, from up to bottom, comprise but not limited to a waveguide layer, a limitation layer, a transition layer, and a window layer. Furthermore, an ohmic contact layer can be formed under the window layer. In some embodiments, the second type epitaxial layer is a semiconductor material with a second conductive type and includes several semiconductor layers. The main body material of the second type epitaxial layer can be but not limited to base materials including one or more of Ga, N, As, P, In, or Al etc. Additionally, the second type epitaxial layer can, from up to bottom, include but not limited to a limitation layer, and a waveguide layer. Furthermore, in some embodiments, an ohmic contact layer can but not limited to be formed on the limitation layer.

In some embodiments, a top conductive layer may be formed on a top surface of micro LED array 112. In some embodiments, the top conductive layer may be shared by all micro LEDs of micro LED array 112. In some embodiments, micro LED array 112 may include a single layer of micro LEDs. For example, the micro LEDs can be arranged on a plane. In some embodiments, micro LED array 112 may include multiple layers of micro LEDs vertically stacked with electrical connection layers. Each micro LED of micro LED array 112 can be respectively controlled by separately controlling an anode and a cathode of each micro LED, or by controlling a common anode electrode layer and respective cathodes of the micro LEDs, or by controlling a cathode electrode layer and respective anodes of the micro LEDs. For example, the micro LEDs can be arranged on several planes which are parallel to each other.

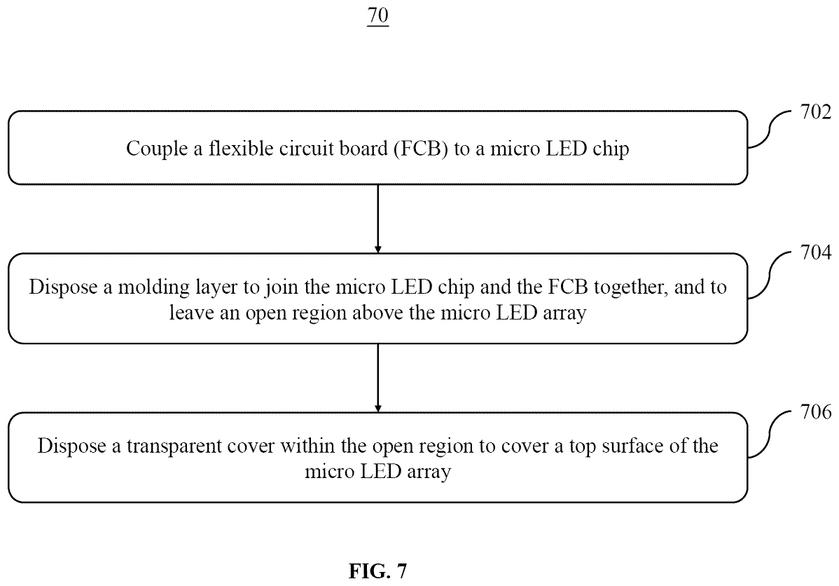

FIG. 7 illustrates a flowchart of an exemplary method 70 of manufacturing a micro LED display panel, according to some embodiments of the present disclosure. As shown in FIG. 7, method 70 includes steps 702 and 704, which can be implemented by a manufacturing device (e.g., a manufacturing device including a die attach machine, a wire bonding machine, a molding machine, a cutting machine, etc.) for making micro LED display panel.

In step 702, the manufacturing device may couples a flexible circuit board (FCB) to a micro LED chip. As described in connection with FIGS. 1A to 6, the micro LED chip comprises a driving layer and a micro LED array disposed on the driving layer. The driving layer may comprise a signal zone on which the micro LED array is not disposed. The signal zone may be used to receive signals for driving the micro LED array. In addition, the manufacturing device may dispose the FCB adjacent to the signal zone and couple it to the signal zone in a connection zone of the FCB.

In some embodiments, the FCB includes conductive traces that lead out from the connection zone. The FCB can be coupled to the signal zone via the traces. In step 702, a molded layer is further disposed to encapsulate the traces.

In step 704, the manufacturing device forms the molded layer to bond the micro LED chip and the FCB into a single compact structure, and leave an open region above the micro LED array.

In step 706, the manufacturing device may dispose a transparent cover within the open region to cover a top surface of the micro LED array.

In some embodiments of the present disclosure, method 70 may further include a step of disposing a light shading layer on metal pads arranged in a signal zone on a front surface of the driving layer, which can be implemented by the manufacturing device.

In some embodiments of the present disclosure, method 70 may further include a step of disposing a substrate layer cooperatively with the molded layer to join the micro LED chip and at least a portion of the FCB, which can be implemented by the manufacturing device. This step can be implemented before disposing the molded layer in step 704. In this step, the molded layer, the micro LED chip, and the connection zone of the FCB can be disposed on a front surface of the substrate layer.

The other aspects of method 70 can be understood by referring to the description above with reference to FIGS. 1A to 6, and will not be described in detail here.

Some embodiments of the present disclosure also provide a display device. The display device may include any of the micro LED display panels described herein.

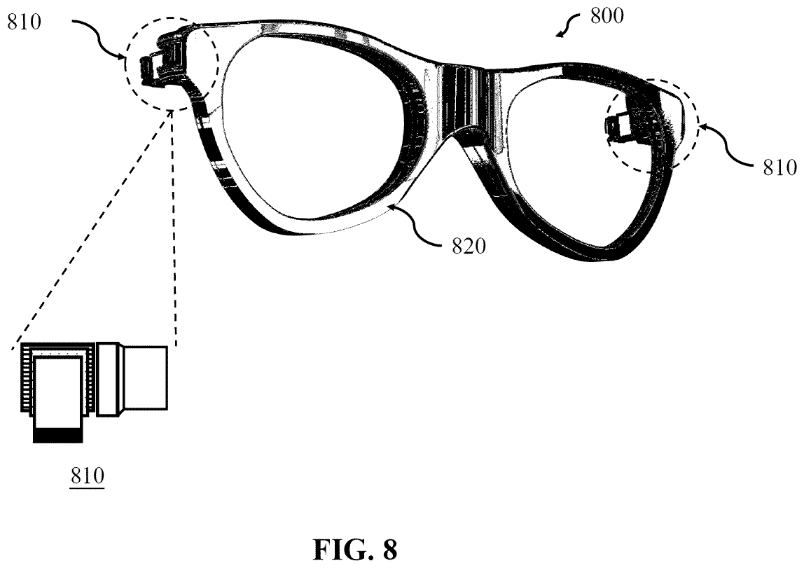

FIG. 8 illustrates an exemplary display device, according to some embodiments of the present disclosure. As shown in FIG. 8, a near eye display (NED) 800, for example AR glasses, includes a pair of polychrome projectors 810 and a frame 820 for securing polychrome projectors 810. NED 800 may also include other components which are omitted here for the purpose of clearly illustrating the configuration of NED 800. Each polychrome projector 810 can be arranged at an end of a temple (not shown) of NED 800, respectively. A power system and a processing system to drive polychrome projectors 810 can be embedded in the temple. Images rendered by each polychrome projector 810 can be captured by respective eyes of a viewer (not shown), which can be used to create a virtual scene or an augmented scene for the viewer. In some embodiments, the term “render” may also be referred to as “display,” “show” or an equivalent. Each polychrome projector 810 may include three micro LED panels (e.g., each corresponding to micro LED display panel 10 in FIGS. 1A, 1B, 2A and 2B, or micro LED display panel 40 in FIGS. 4A and 4B) of different colors and a combiner (e.g., a combining prism). The combiner can be used to combine (also referred to as “compositing”) the images rendered the three micro LED panels into a composite image.

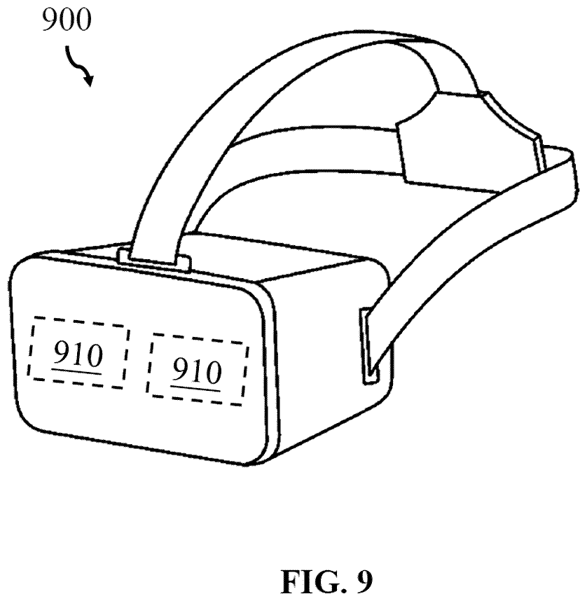

FIG. 9 illustrates another exemplary display device, according to some embodiments of the present disclosure. As shown in FIG. 9, a head-mounted virtual reality device 900 includes two micro LED panels 910 (e.g., each corresponding to micro LED display panel 10 in FIGS. 1A, 1B, 2A and 2B, or micro LED display panel 40 in FIGS. 4A and 4B). Although not shown, head-mounted virtual reality device 900 may also include a central processing unit (CPU), a graphic processing unit (GPU) acting as a signal source, and other related circuitries. The introduction of micro LED panels that embody the micro LED elements described above in head-mounted virtual reality device 900 can improve the lighting efficiency thereof, hence reducing energy consumption and improving imaging quality.

It should be noted that the relational terms herein such as “first” and “second” are used only to differentiate an entity or operation from another entity or operation, and do not require or imply any actual relationship or sequence between these entities or operations. Moreover, the words “comprising,” “having,” “containing,” and “including,” and other similar forms are intended to be equivalent in meaning and be open ended in that an item or items following any one of these words is not meant to be an exhaustive listing of such item or items, or meant to be limited to only the listed item or items.

As used herein, unless specifically stated otherwise, the term “or” encompasses all possible combinations, except where infeasible. For example, if it is stated that a database may include A or B, then, unless specifically stated otherwise or infeasible, the database may include A, or B, or A and B. As a second example, if it is stated that a database may include A, B, or C, then, unless specifically stated otherwise or infeasible, the database may include A, or B, or C, or A and B, or A and C, or B and C, or A and B and C.

In the foregoing specification, embodiments have been described with reference to numerous specific details that can vary from implementation to implementation. Certain adaptations and modifications of the described embodiments can be made. Other embodiments can be apparent to those skilled in the art from consideration of the specification and practice of the invention disclosed herein. It is intended that the specification and examples be considered as exemplary only, with a true scope and spirit of the invention being indicated by the following claims. It is also intended that the sequence of steps shown in figures are only for illustrative purposes and are not intended to be limited to any particular sequence of steps. As such, those skilled in the art can appreciate that these steps can be performed in a different order while implementing the same method.

In the drawings and specification, there have been disclosed exemplary embodiments. However, many variations and modifications can be made to these embodiments. Accordingly, although specific terms are employed, they are used in a generic and descriptive sense only and not for purposes of limitation.

What is claimed is:

1. A micro LED display panel, comprising:
a micro LED chip comprising a driving layer and a micro LED array disposed on the driving layer, the driving layer being configured to receive signals for driving the micro LED array;
a flexible circuit board (FCB) disposed adjacent to the micro LED chip and configured to couple to the micro LED chip;
a molded layer disposed on the micro LED chip and the FCB to join the micro LED chip and the FCB together, to leave an open region above the micro LED array; and
a transparent cover disposed within the open region to shield a top surface of the micro LED array.

2. The micro LED display panel according to claim 1, wherein the driving layer further comprises a signal zone on which the micro LED array is not disposed, and the FCB is disposed adjacent to the signal zone and coupled to the signal zone.

3. The micro LED display panel according to claim 2, wherein the FCB further comprises a connection zone adjacent to the signal zone, and
the micro LED display panel further comprises conductive traces connected between the connection zone and the signal zone.

4. The micro LED display panel according to claim 1, wherein the transparent cover is spaced from the top surface of the micro LED array.

5. The micro LED display panel according to claim 1, wherein the transparent cover comprises an adhesive layer that is adhered to the driving layer, around the top surface of the micro LED array.

6. The micro LED display panel according to claim 5, wherein the adhesive layer is formed by epoxy adhesive, thermosetting adhesive, or moisture adhesive.

7. The micro LED display panel according to claim 5, wherein the driving layer further comprises:
metal pads on a front surface of the driving layer; and
a light shading layer disposed on the metal pads.

8. The micro LED display panel according to claim 7, wherein the metal pads and the light shading layer are formed around the micro LED array.

9. The micro LED display panel according to claim 8, wherein the adhesive layer is formed on a top surface of the light shading layer.

10. The micro LED display panel according to claim 1, wherein a side surface of the transparent cover is spaced from the molded layer.

11. The micro LED display panel according to claim 2, further comprising:
a substrate layer disposed cooperatively with the molded layer to join the micro LED chip and at least a portion of the FCB, wherein the molded layer, the micro LED chip, and the FCB are disposed on a front surface of the substrate layer.

12. The micro LED display panel according to claim 11, wherein the substrate layer is formed by a steel plate.

13. The micro LED display panel according to claim 11, wherein the FCB comprises an adhesive layer adhered to a surface of the substrate layer, a bottom surface of the adhesive layer aligned with a bottom surface of the micro LED chip.

14. The micro LED display panel according to claim 13, wherein the adhesive layer is conductive.

15. The micro LED display panel according to claim 13, wherein the adhesive layer is a first adhesive layer, and the driving layer further comprises a second adhesive layer that is adhered to the surface of the substrate layer, a bottom surface of the second adhesive layer aligning with a bottom surface of the FCB.

16. The micro LED display panel according to claim 15, wherein the second adhesive layer is insulative.

17. The micro LED display panel according to claim 16, wherein the second adhesive layer is formed by Die Attach (DA) adhesive or Die Attach Film (DAF) adhesive.

18. The micro LED display panel according to claim 15, wherein a thickness of the first adhesive layer is less than a thickness of the second adhesive layer.

19. The micro LED display panel according to claim 13, wherein the FCB is coupled to the signal zone in a connection zone of the FCB, the adhesive layer is disposed on a bottom surface of the connection zone, and the substrate layer is disposed below the connection zone via the adhesive layer.

20. The micro LED display panel according to claim 19, wherein the adhesive layer is further disposed below a bottom surface of a region adjacent to the connection zone, the substrate layer being further disposed below the adjacent region via the adhesive layer.

21. The micro LED display panel according to claim 20, wherein the molded layer is further formed on the FCB at a distance extending from the connection zone.

22. The micro LED display panel according to claim 21, wherein the distance equals to or differs from a length of the adjacent region.

23. The micro LED display panel according to claim 22, wherein the distance is at least 0.05 mm longer than the length of the adjacent region.

24. The micro LED display panel according to claim 2, wherein the FCB is coupled to the signal zone in a connection zone of the FCB, the FCB comprising conductive traces that lead out from the connection zone, and the FCB is coupled to the signal zone via the traces.

25. The micro LED display panel according to claim 24, wherein the molded layer is further disposed to encapsulate the traces.

26. The micro LED display panel according to claim 1, wherein a bottom surface of the micro LED chip is aligned with a bottom surface of the FCB.

27. The micro LED display panel according to claim 1, wherein a height of the molded layer is higher than or equals to a height of the micro LED array.

28. The micro LED display panel according to claim 2, wherein the FCB is coupled to the signal zone in a connection zone of the FCB, a width of the molded layer corresponds to a width of the connection zone, and the width of the molded layer is greater than a width of all regions of the FCB other than the connection zone.

29. The micro LED display panel according to claim 1, further comprising a hard circuit board provided on the FCB at an opposite end to the micro LED chip and electrically coupled to the FCB, the hard circuit board comprising at least one connector disposed on a surface of the hard circuit board.

30. The micro LED display panel according to claim 29, wherein the hard circuit board further comprises a memory chip, the at least one connector being coupled to the memory chip.

31. A method of manufacturing a micro LED display panel, comprising:
coupling a flexible circuit board (FCB) to a micro LED chip, the micro LED chip comprising a driving layer and a micro LED array disposed on the driving layer, the driving layer being configured to receive signals for driving the micro LED array, the FCB being disposed adjacent to the micro LED chip and configured to couple to the micro LED chip;
forming a molded layer to bond the micro LED chip and the FCB into a single structure, leaving an open region above the micro LED array; and
disposing a transparent cover within the open region to cover a top surface of the micro LED array.

32. The method according to claim 31, wherein the driving layer further comprises a signal zone on which the micro LED array is not disposed, and the FCB is disposed adjacent to the signal zone and coupled to the signal zone.

33. The method according to claim 32, wherein the FCB further comprises a connection zone adjacent to the signal zone, and
the micro LED display panel further comprises conductive traces connected between the connection zone and the signal zone.

34. The method according to claim 31, further comprising:
disposing a light shading layer on metal pads arranged on a front surface of the driving layer.

35. The method according to claim 31, wherein before forming the molded layer, the method further comprises:
disposing a substrate layer on a back surface of the micro LED chip and at least a portion of the FCB, the substrate layer and the molded layer collaboratively joining the micro LED chip and the FCB.

36. The method according to claim 32, wherein the FCB comprises conductive traces led out from a connection zone, the FCB being configured to couple to the signal zone via the traces.

37. The method according to claim 36, wherein the molded layer is further formed to encapsulate the traces.

38. A display device, comprising a micro LED display panel, wherein the micro LED display panel comprises:
a micro LED chip comprising a driving layer and a micro LED array disposed on the driving layer, the driving layer being configured to receive signals for driving the micro LED array;
a flexible circuit board (FCB) disposed adjacent to the micro LED chip and configured to couple to the micro LED chip;
a molded layer disposed on the micro LED chip and the FCB to join the micro LED chip and the FCB together, to leave an open region above the micro LED array; and
a transparent cover disposed within the open region to shield a top surface of the micro LED array.
